(19) United States
(12) Patent Application Publication
(10) Pub. No.: US 2016/0381819 A1
(43) Pub. Date: Dec. 29, 2016

(54) DEVICE COVER AND ELECTRONIC PORT EXTENDER FOR AN ELECTRONIC DEVICE

(71) Applicant: Lawrence F. GLASER, Fairfax Station, VA (US)

(72) Inventor: Lawrence F. GLASER, Fairfax Station, VA (US)

(21) Appl. No.: 14/901,955

(22) PCT Filed: Jun. 28, 2014
(86) PCT No.: PCT/US14/44760

§ 371 Date: Dec. 29, 2015

Related U.S. Application Data
(60) Provisional application No. 61/841,331, filed on Jun. 29, 2013.

(51) Int. Cl. H05K 5/02; H05K 5/03

(52) U.S. Cl. CPC H05K 5/0217; H05K 5/0247; H05K 5/03

(57) ABSTRACT

A dongle or port extender and a cover design for electronic devices is provided. The port extender replicates a port on a given electronic device, and port extenders may be provided for all ports, including electrical and fiber optic ports. The replication of some or all of the ports by the separable port extender provides the ability to inexpensively repair a port by the replacement of the port extender.

### CROSS-REFERENCE TO RELATED APPLICATIONS

This application claims the benefit of priority to U.S. Provisional Patent Application No. 61/841,331, filed on Jun. 29, 2013, which is hereby incorporated by reference in its entirety.

### TECHNICAL FIELD

This disclosure relates to covers for electronic devices that serve to protect and/or provide water resistance to an electronic device. Such device covers may be provided as an after-market add-on, attached to a housing or case of an electronic device during manufacturing, or may be directly formed on a housing or case for an electronic device.

### BACKGROUND

Electronic devices, such as personal portable phones, which may also be described as cell phones, mobile phones, etc., tablets, and MP3 players, are subject to significant wear and damage through use and contact with other objects, or being dropped. A variety of protective sleeves, masks, covers, shrouds, etc., have been provided to reduce damage and wear and tear to electronic devices.

Electronic devices also include a plurality of electrical or electronic ports. Such electrical or electronic ports may connect power and data to and from the electronic device.

### SUMMARY

Advantages and features of the embodiments of this disclosure will become more apparent from the following detailed description of exemplary embodiments when viewed in conjunction with the accompanying drawings.

### BRIEF DESCRIPTION OF THE DRAWINGS

FIG. 1 shows a form--fitted top cover and a form-fitted bottom covers for an electronic device in accordance with an exemplary embodiment of the present disclosure, including electronic port extenders in accordance with an exemplary embodiment of the present disclosure.

FIG. 2 shows an electronic port extender in accordance with a first exemplary embodiment of the present disclosure.

FIG. 3 shows an electronic port extender in accordance with a first exemplary embodiment of the present disclosure.

FIG. 4 shows an electronic device, an electronic port extender, and an electronic device cover in accordance with an exemplary embodiment of the present disclosure.

FIG. 5 shows a portion of the electronic device, electronic port extender, and electronic device cover of FIG. 4, with the electronic port extender installed.

FIG. 6 shows a sectional view of the electronic device, electronic port extender, and electronic device cover of FIG. 5 along the lines 6-6.

FIG. 7 shows electronic port extenders in accordance with exemplary embodiments of the present disclosure.

### DETAILED DESCRIPTION

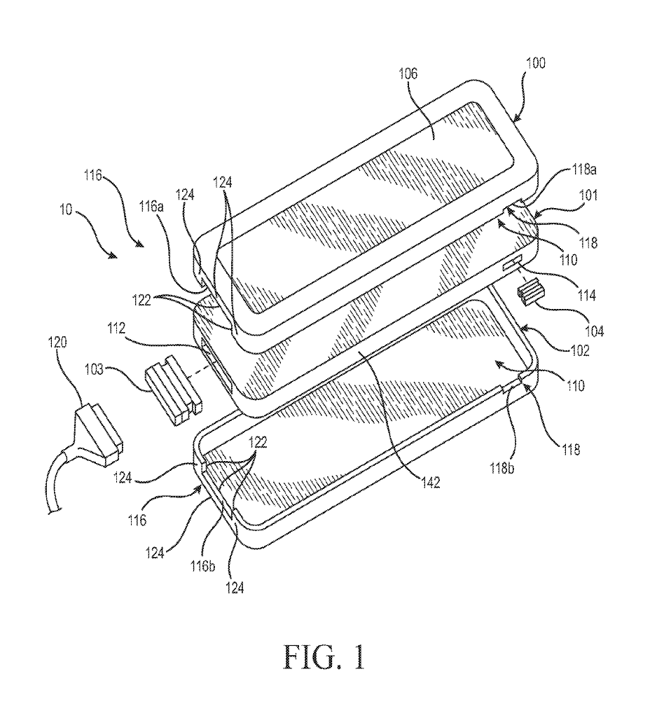

An exemplary embodiment electronic device cover assembly is shown in FIG. 1 and generally indicated at 10. Device cover assembly 10 is secured to an electronic device 101 to provide protection for electronic device 101. Device cover assembly 10 may include one or more electronic port extenders or dongles 103 and 104, though dongles 103 and 104 may be provided as separate devices. Dongles 103 and 104 are electronic devices that electrically connect to a mating electronic port positioned in electronic device 101. Device cover assembly 10 secures dongles 103 and 104 to electronic device 101 relatively rigidly, as will be described further herein, reducing stress on the mating electronic ports of electronic device 101. Because the dongles described herein provided a connection between two connectors, the dongles described herein may also be described as null dongles.

Stress from connectors that would normally attach to the mating electronic ports of electronic device 101 is transmitted instead to dongles 103 and 104. If dongle 103 or dongle 104 becomes damaged, the damaged dongle can be easily, quickly, and inexpensively replaced in comparison to replacing or repairing the mating electronic ports of electronic device 101, which are relatively expensive to repair, requiring a skilled technician and potentially significant time to repair. During the time it takes to repair an electronic port of electronic device 101, electronic device 101 will be unavailable to a user. If electronic device 101 is, for example, a cell phone or a tablet used for work, the unavailability may represent a significant inconvenience, and potentially a loss of productivity, or even a loss of business. Thus, device cover assembly 10, and dongles 103 and 104 represent a significant improvement in the reliability of the electrical ports of an electronic device 101.

While an electronic device may include an exterior shell that may be described by a variety of terms, such as housing, cover, shell, case, skin, etc., the exterior housing of the electronic device will be described as the case for simplicity, consistency, and clarity. Similarly, while the term cover is used to describe a separate element that may be formed on or attached to the case, the term cover may be replaced by other terms, such as separate case, shell, skin, housing, etc. To reduce the chance for confusion with the case of an electronic device, the separate housing portion will be described as a cover or cover portions for simplicity, consistency, and clarity.

In the exemplary embodiment of FIG. 1, one or more dongles, dongles 103 and 104, are positioned in a first electrical or electronic port 112 and a second electrical or electronic port 114, respectively. It should be understood that dongles 103 and 104 are used to represent an array of potential dongles for electrical devices. For example, in an exemplary embodiment, an electronic device may have one electrical port, and thus, only one dongle would be required. In another exemplary embodiment, an electronic device may have three or more electronic ports, and thus, numerous port extenders or dongles would be needed. Further, dangles may mate with a variety of electrical port types, including USB, IEEE 1394 high speed serial bus, parallel SCSI, DC power ports, AC power ports, etc. As will be understood from the exemplary embodiments presented herein, any electrical port can benefit from the features of the present disclosure. Further, though the term “electrical” and “electronic are used in conjunction with the exemplary embodiments, it will be understood that other ports may benefit from the features of the present disclosure, such as fiber optic ports.

Device cover assembly 10 includes a first or top cover 100 and a second or bottom cover 102. At least one of top cover 100 and bottom cover 102 includes one or more openings formed therein that permit dongles to extend from first electrical port 112 or second electrical port 114 through top cover 100 and/or bottom cover 102 to permit the dongles to be accessible from an exterior of top cover 100 and/or bottom cover 102. In the exemplary embodiment of FIG. 1, top cover 100 includes a portion of a first opening 116a and a portion of a second opening 1.18a, and bottom cover 102 includes a portion of a first opening 116b and a portion of a second opening 188b. Top cover 100 may further include a transparent integral membrane or film 106 that permits viewing of a display 126 of electronic device 101 and actuation of buttons 128, as shown in, for example, FIG. 4, or a touch screen of electronic device 101.

In the exemplary embodiment of Ha 1, first or top cover 100 is positioned on a first side of an electronic device 101, and second or bottom cover 102 is positioned on a second side of electronic device 101. Either top cover 100 engages bottom cover 102 or bottom cover 102 engages top cover 100 to secure electronic device 101 in an interior cavity, hollow, compartment, or chamber 110. When top cover 100 and bottom cover 102 are engaged to each other, capturing or restraining electronic device 101, top cover 100 and bottom cover 102 also capture or contact dongles 103 and 104, which extend through a first opening 116 formed by first opening portions 116a and 116b, and through a second opening 118 formed by second opening portions 118a and 118b, respectively. As will be seen, by capturing dongles 103 and 1.04, dongles 103 and 104 are held relatively rigidly with respect to first electrical port 112 and second electrical port 114, respectively. It should also be noted that each opening if positioned in the area of or adjacent to at least one electrical port. In the exemplary embodiment of FIG. 1, first opening 116 is adjacent to first electrical port 112 and second opening 118 is adjacent to second electrical port 114.

Prior to installing any device cover, such as device covers, the dongles may be tested to verify the dongle-electrical port interface, the functioning of the electrical port, and the functioning of the dongle. Once the dongles, such as dongles 103 and 104 of FIG. 1, are installed, associated cables, such as cable and connector assembly 120, may be connected to the appropriate dongle, such as dongle 103. Now power or data may be routed to or from electronic or electrical device 101 to determine whether the various components are functioning properly, prior to installation of top cover 100 and bottom cover 102.

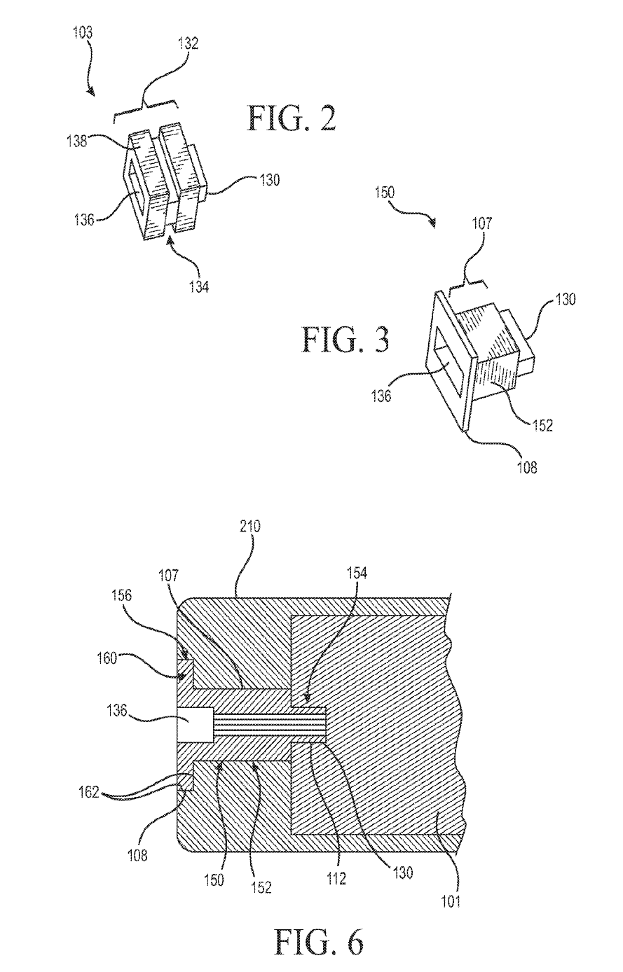

Referring to FIG. 2, port extender or dongle 103 is described in more detail. Dongle 103 includes, in a longitudinally-extending direction, a first connector 130, a side portion 132 including a groove or channel 134 formed therein, and a second connector 136. First connector 130 mates with an electrical port of an electronic device, for example, first electrical port 112 of electronic device 101. Typically, second connector 136 is identical to first electrical port 112, though it need not be identical to first electrical port 112, and thus, in instances where second connector 136 is identical to first electrical port 112, dongle 103 may be described as a replica port. Second connector 136 mates with another connector, for example, a connector of cable 120, shown in FIG. 1. In an exemplary embodiment, top cover 100 and bottom cover 102 include a region 122 adjacent to first opening 116. When top cover 100 and bottom cover 102 are engaged with each other, with electronic device 101 positioned in cavity 110, and dongles 103 and 104 positioned in first electrical port 112 and second electrical port 114, region 122, which includes a wall portion 124, extends into groove 134, engaging and capturing dongle 103. Dongle 104 may be similarly configured.

A body portion 138 of dongle 103 may be formed of a compliant material, such as nitrite, or other similar materials. Consequently, contact between body portion 138 and regions 122 of top cover 100 and bottom cover 102 may provide resistance to water and debris passing along the interface between body portion 138 and top cover 100 and bottom cover 102. Furthermore, top cover 100 and bottom cover 102 are configured to mate with a shape of a case 142 of electronic device 101 to limit or reduce the movement of electronic device 101 with respect to top cover 100 and bottom cover 102. In order to reduce shocks communicated to electronic device 101 that electronic device cover assembly 10 may receive, top cover 100 and bottom cover 1102 may be formed of a resilient material, or may include a cushioning material (not shown) in cavity 100.

A second exemplary embodiment dongle is shown in FIG. 3 and generally indicated at 150. Similar to dongle 103, dongle 150 includes interior first connector 130 and exterior second connector 136. Dongle 150 further includes a body 152 that may be made of a flexible or compliant material to provide environmental resistance when mated with a cover, described further herein. Rather than engaging a groove formed in the side of the dongle, as is the case with exemplary dongle 103, body 152 of dongle 150 includes a plurality of substantially fiat side surfaces 107 that provide a friction fit with surfaces adjacent to an opening in a device cover, described further herein. Dongle 150 may further include a flange 108 that mates with a recess 160, formed by a recess wall 162, as shown in FIG. 6, formed in the device cover. In another embodiment, recess wall 162 may be configured to engage groove 134 of dongle 103. Flange 108 may be sized and dimensioned such that an exterior surface of flange 108 is substantially flush with an exterior surface of a device cover, forming a smooth finish over a replicated or extended electronic port so as to avoid wear, tear and snagging on the flange of the dongle or the opening in which the dongle is position.

Flange 108 may be used to limit the amount of force applied to an electrical port, such as electrical port 112, by mating electrical connector 130 during installation of dongle 150. Flange 108 may also assist in limiting the movement of dongle 150 under a variety of conditions, thus stabilizing dongle 150. The advantage to dongle 150 is that it may be installed or removed without removing the device cover first.

When using the configuration of dongle 150, as with dongle 103, a user can plug dongles into their respective ports and test the respective electronic ports and dongle 150 by using the electronic port(s) for their specific functions, such as power or data input or output.

Referring to FIG. 4, a cover 200 in accordance with an exemplary embodiment of the present disclosure is shown, which protects a peripheral rim 140 of electronic device 101. Cover 200 is compatible with dongle 150 and is configured to limit the movement or substantially immobilize dongle 150 with respect to electronic device 101, and particular the ports of electronic device 101.

Cover 200 may be rigid or firm, semi-rigid, or flexible. In configurations where cover 200 is rigid or semi-rigid, cover 200 “snaps” over rim 140 to engage electronic device 101. In configurations where cover 200 is made of a flexible, compliant, or stretchable material, e.g., rubberized material, cover 200 stretches or expands slightly for installation on electronic device 101, and form fits to electronic device 101 when installed.

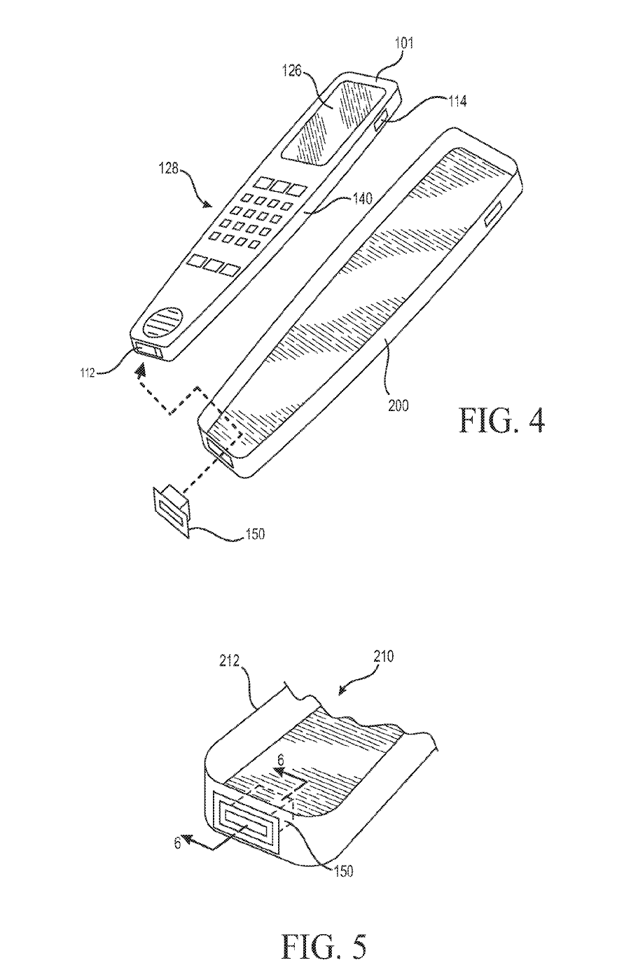

Referring to FIGS. 5 and 6, a cover 210 in accordance with an exemplary embodiment of the present disclosure is shown. Cover 210 is similar to cover 200, however cover 210 is made of a flexible material, and dongle 150, or a dongle similar to dongle 150, is captured by cover 210; i.e., dongle 150 is integral with cover 210. Typically, the end of cover 210 that includes dongle 150 would be installed before stretching a flexible rim or periphery 212 of cover 210 about a perimeter or rim 140 of electronic device 101.

Referring to FIG. 6, which eliminates some details for clarity, a portion of electronic device 101 and device cover 210 are shown, with dongle 150 installed. Dongle 150 is constrained at a first location 154 by contact with first electrical port 112 and at a second location 156 by contact of flange 108 with cover 210. Further, frictional engagement or contact of side surfaces 107 with device cover 210, i.e., further constrains dongle 150, thus reducing or preventing angular movement between dongle 150 and first electrical port 112, which reduces stress on first electrical port 112. By reducing stress on first electrical port 112, first electrical port 112 achieves greater reliability. Of course, if dongle 150 should fail, it may be easily removed and replaced, restoring the functionality of electronic device 101 rapidly, providing improved user satisfaction and increasing the desirability of electronic device 101.

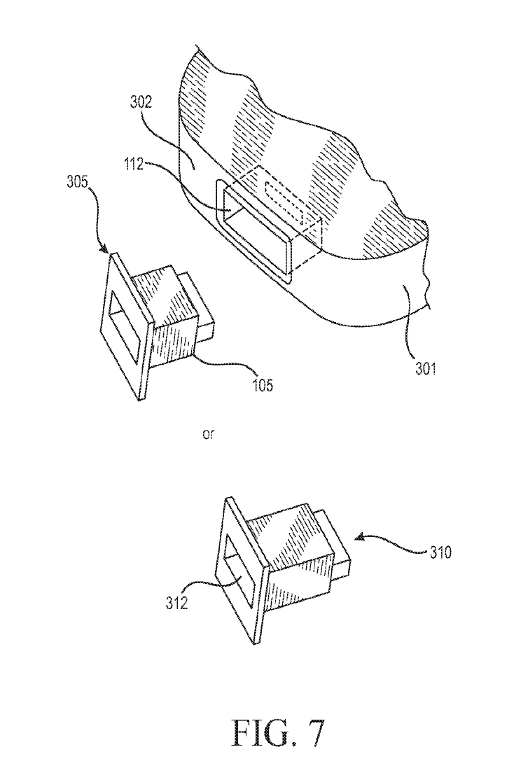

FIG. 7 shows an electronic device, which may be a cell phone 301, in accordance with an exemplary embodiment of the present disclosure, and differing from electronic device or cell phone 101 in that cell phone 301 has incorporated the removable null dongle concept in its factory design; i.e., its original design, as received by the end user out of the box. Cell phone 301 includes a dongle 305 that is similar to dongle 150, and may be identical to dongle 150. In another exemplary embodiment, cell phone 301 may include a dongle 310 that includes a greater length than dongle 305, thus positioning an opening of second connector 312 a spaced distance from an exterior surface 302 of cell phone 301. The benefit of the configuration of dongle 310 is that permits the user to adapt a new external case (not shown) to cell phone 301 while interlocking with dongle 310.

A significant advantage to the dongle configuration is that a user or a manufacturer can include a dongle as part of a cover kit, which decreases design complexity for highly robust electronic device covers having relatively thick walls. In existing configurations, an electrical or optical port can become distanced from an exterior surface of a cover that the port is difficult to access, leading to connection challenges, and potentially requiring pulling on a wire to disconnect a cable, which weakens the cable. The dongle of the present disclosure solves these problems by keeping exterior ports near a surface where they can be easily accessed.

Certain features have been omitted from the figures for clarity and simplicity of explanation. For example, screws, snap springs, pins, or tangs may be used to secure various elements to each other for added rigidity or environmental isolation.

While not shown, the dongles of the present disclosure are adaptable to other cover configurations. For example, a cover may be incorporated on an electrical device through a dipping or an insert molding process, where a cover is formed about an external case of the electronic device, though the case itself may also be produced by such a process. Further, a cover may be formed directly on an electronic device by a printing process, such as via a 3D printer. Because of the adaptability of the dongle configuration, such configurations would either be compatible with cover variations, or could be configured to be compatible with a cover variation, as one of skill could readily acquire upon reading of this specification and review of the drawings.

The dongles and covers of the present disclosure are thus extremely versatile to be compatible with a large range prior art devices, In an embodiment, the invention can be made as a low cost kit, providing modest protection. In another embodiment, a kit may be provided with such features as a powered case that illuminates in the dark, provides signal tracking and a beacon, port replicators (with null dongles), and a UV, dirt, and moisture protective film for the display portions of the device. Other embodiments of the invention include a continuum of intermediate embodiments, along a cost axis.

We claim:

1. An electronic device, comprising:
a case having a shape and including an electronic port;
a device cover including surfaces forming at least one opening extending therethrough, the device cover configured to mate with the shape of the case, and the opening is positioned adjacent to the electronic port; and
a dongle extending through the at least one opening to mate with the electronic port; wherein
the dongle is configured to engage the device cover.

2. The electronic device of claim 1, wherein the device cover is formed of a flexible stretching material.

3. The electronic device of claim 1, wherein the dongle has an installed position in which the dongle is engaged with the surfaces, substantially immobilizing the dongle with respect to the device cover.

4. The electronic device of claim 1, wherein the device cover further comprises a rim extending around the perimeter of the device.

5. The electronic device of claim 4, wherein said rim is flexible.

6. The electronic device of claim 1, wherein the dongle extends substantially beyond the perimeter of the electronic device case.

7. The electronic device of claim 1, wherein the dongle is removably positioned in the device cover and connected to the electronic device.

8. The electronic device of claim 1, wherein the dongle includes a groove for engaging walls adjacent to the surfaces.

9. The electronic device of claim 1 wherein the device cover includes a recess wall form a recess positioned adjacent the surfaces and the dongle includes a flange that mates with the recess.

10. The electronic, device according to claim 9, wherein an exterior surface of the flange is flush with an exterior surface of the device cover.

11. The electronic device of claim 1, the device cover further including a transparent film positioned to permit viewing of a display of the electronic device.

12. A device cover kit for an electronic device, comprising:
a device cover including at least one opening extending therethrough, the device cover configured to mate with a case of the electronic device; and
a dongle having a first connector configure to mate with a connector of the electronic device, and a second conductor, the dongle configured to extend through the at least one opening; wherein
the dongle is configured to engage the device cover.

13. The device kit of claim 12 wherein the dongle is integrally manufactured with the case.
